(19) United States
(12) Patent Application Publication
(10) Pub. No.: US 2024/0249757 A1
(43) Pub. Date: Jul. 25, 2024

(54) GENERATING A RANDOM NUMBER USING A NON-VOLATILE MEMORY BASED PHYSICAL UNCLONEABLE FUNCTION

(71) Applicant: Western Digital Technologies, Inc., San Jose, CA (US)

(72) Inventor: Asaf Gueta, Ganei Tikva (IL)

(21) Appl. No.: 18/357,208

(22) Filed: Jul. 24, 2023

Related U.S. Application Data
(60) Provisional application No. 63/480,709, filed on Jan. 20, 2023.

(51) Int. Cl. G11C 7/24; G11C 7/10

(52) U.S. Cl. CPC G11C 7/24; G11C 7/1063; G11C 7/1069

(57) ABSTRACT

A true random number is generated using a non-volatile memory based physical unclonable function (PUF). To generate the random number, an identified page (or block) of a memory die of the non-volatile memory is programmed or erased such that all, or substantially all, of the memory cells of the identified page are in the same state. A soft sense or soft read operation applies various different read threshold voltages to the memory cells until approximately half of the memory cells of the identified page are read as being in one state while the approximately other half of the memory cells of the identified page are read as being in another state. The identified page may then be read or sensed using the determined read threshold voltage. Raw data, which represents a true random number, is then provided to a controller or other requesting computing device.

### CROSS-REFERENCE TO RELATED APPLICATIONS

The present application claims priority to U.S. Provisional Application 63/480,709 entitled “GENERATING A RANDOM NUMBER USING A NON-VOLATILE MEMORY BASED PHYSICAL UNCLONEABLE FUNCTION”, filed Jan. 20, 2023, the entire disclosure of which is hereby incorporated by reference in its entirety.

### BACKGROUND

Physical unclonable functions (PUFs) are unique physical features or elements of a semiconductor device, such as, for example, a non-volatile memory device. A PUF is based on or otherwise generated from physical conditions of the semiconductor device such as, for example, associated processes, supply voltages and/or temperatures. During semiconductor manufacturing, physical variations naturally occur between similar devices. PUF relies on these variations to generate a unique identifier or “fingerprint” of the semiconductor device. For example, when a physical stimulus is applied to the semiconductor device, the semiconductor device will respond in a unique and unclonable manner.

Today, many different types of PUFs exist. For example, traditional non-volatile memory devices typically utilize a ring oscillator PUF to generate the unique identifier or other random number. However, a ring oscillator PUF typically uses circuitry that occupies valuable real estate on the silicon of the non-volatile memory device. Additionally and in some cases, when a unique identifier or other random number is generated for the non-volatile memory device (or for other semiconductor devices), the generated unique identifier or random number may be stored, which may pose a security risk.

Accordingly, it would be beneficial for a semiconductor device to generate a unique identifier or random number without requiring extra circuitry and without subsequently storing the unique identifier or random number.

### SUMMARY

The present application describes generating a true random number using a non-volatile memory based physical unclonable function (PUF). In order to generate the true random number using PUF, an identified page of a memory die of the non-volatile memory may be programmed or erased such that all (or substantially all) of the memory cells of the page are in the same state. For example, all or substantially all of the memory cells associated with the page may be in an erased state (e.g., have a value of “1”) or may be in a programmed state (e.g., have a value of “0”). Once the identified page has either been programmed or erased, a read threshold voltage is determined (e.g., using a trial and error method approach or a brute force approach) that causes approximately half (e.g., approximately fifty percent) of the memory cells of the identified page to be read as one state while the approximately other half of the memory cells of the identified page are read as another state-regardless of whether the memory cells associated with the identified page were initially in an erased state or programmed state.

For example, if the memory cells of the identified page are initially in an erased state, various different read threshold voltages are applied (e.g., using a soft read or soft sense operation using a special read threshold voltage) to the identified page. After each different read threshold voltage is applied, a determination is made as to whether approximately fifty percent of the memory cells are sensed/read to be in a programmed state and/or whether approximately fifty percent of the memory cells are sensed/read to be an erased state.

In some examples, the PUF associated with the non-volatile memory may cause each memory cell to behave in a certain way when each read threshold voltage is applied to the page. For example, process, voltage and/or temperature characteristics associated with the memory die on which the identified page is stored, the memory block in which the identified page is stored and/or the identified page itself may cause different memory cells to be read to have different values.

Once the actual read threshold voltage (e.g., the read threshold voltage that causes approximately half of the memory cells to be read as being in a first state and causes approximately half of the memory cells to be read as being in a second state that is different from and/or opposite the first state) is determined, the page is read or sensed using the actual read threshold voltage. In an example, the read operation or sensing operation may be one in which the data associated the identified page is provided to an internal ledger of the non-volatile memory device. The raw data (which represents a true random number) may subsequently be provided to a controller or other computing device associated with the non-volatile memory.

Accordingly, the present application describes a method for generating a random number using a non-volatile memory based physical unclonable function (PUF). In an example, the method includes identifying a page of a memory die of a non-volatile memory device. When the page has been identified, a plurality of memory cells associated with the identified page is programmed or erased such that the memory cells associated with the identified page are in a first state. An initial read threshold voltage is determined and a soft read operation is performed on the plurality of memory cells using the initial read threshold voltage. In an example, the soft read operation using the initial read threshold voltage causes a subset of memory cells of the plurality of memory cells to be read as being in a second state that is different than the first state. A determination may then be made as to whether a number of memory cells being read as being in the second state is substantially equivalent to a number of memory cells being read as being in the first state. Based on determining that the number of memory cells being read as being in the second state is substantially equivalent to the number of memory cells being read as being in the first state, an output is generated. In an example, the output may be provided to a requesting computing device.

The present application also describes a data storage device that includes at least one memory die and a controller. The controller is communicatively coupled to the at least one memory die and is configured to identify a page of the memory die. The controller may also cause a plurality of memory cells associated with the identified page to be in a first state. The controller may determine an initial read threshold voltage and perform a soft read operation on the plurality of memory cells using the initial read threshold voltage. In an example, the soft read operation using the initial read threshold voltage causes a subset of memory cells of the plurality of memory cells to be read as being in a second state that is opposite the first state. The controller may also determine whether a number of memory cells being read as being in the second state is substantially equivalent to a number of memory cells being read as being in the first state. Based on a determination that the number of memory cells being read as being in the second state is substantially equivalent to the number of memory cells being read as being in the first state, an output is generated.

Other examples of the present application describe a non-volatile storage device that includes a plurality of memory dies. The non-volatile storage device also includes means for identifying a page of the memory die and means for causing a plurality of memory cells associated with the identified page to be in a first state. The non-volatile storage device also includes means for determining an initial read threshold voltage and means for performing a soft read operation on the plurality of memory cells using the initial read threshold voltage. In an example, the soft read operation using the initial read threshold voltage causes a subset of memory cells of the plurality of memory cells to be read as being in a second state that is opposite the first state. The non-volatile storage device also includes means for determining whether a number of memory cells being read as being in the second state is substantially equivalent to a number of memory cells being read as being in the first state. The non-volatile storage device also includes means for generating an output based on a determination that the number of memory cells being read as being in the second state is substantially equivalent to the number of memory cells being read as being in the first state.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a component diagram of an example memory device that may be used to generate a true random number according to an example.

FIG. 2 illustrates a method for using a non-volatile memory based physical unclonable function (PUF) to generate a true random number according to an example.

FIG. 3 illustrates a method for using a true random number to generate a cryptographic key according to an example.

FIG. 4 illustrates a method for reproducing true random number to decode a cryptographic key according to an example.

FIG. 5A illustrates an example read threshold voltage that may be adjusted based on a determined distribution of 1's and 0's when an identified page of a memory die of a non-volatile memory device has been set to an erase state according to an example.

FIG. 5B illustrates an example read threshold voltage that may be adjusted based on a determined distribution of 1's and 0's when an identified page of a memory die of a non-volatile memory device has been set to a programmed state according to an example.

FIG. 6 is a perspective view of a storage device that includes three-dimensional (3D) stacked non-volatile memory according to an example.

FIG. 7 is a block diagram of a storage device according to an example.

FIG. 8 is another block diagram of a storage device according to an example

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

A physical unclonable function (PUF) may be used to generate a unique value (e.g., a PUF value) that is associated with a particular semiconductor device, such as, for example, a non-volatile memory device. A PUF value may be based on physical manufacturing variations of the particular semiconductor device. For example, although two or more semiconductor devices may be identical, each of the two or more semiconductor devices may have different process, voltage and/or temperature characteristics and/or properties. These variations may be used to produce unclonable responses and/or behavior to a given input (e.g., a read voltage threshold). The PUF value may be used to generate true random numbers and/or other unique identifiers such as will be described in greater detail herein.

In order to generate true random numbers using a PUF value and/or a non-volatile memory PUF, a page of a memory die of a non-volatile memory device (e.g., a NAND memory device) is identified. In an example, any page of the non-volatile memory device may be selected or otherwise identified. In another example, multiple different pages of the non-volatile memory device may be identified and/or selected to generate a number of different true random numbers such as described herein.

Once the page is identified, the page is programmed or erased such that all (or substantially all) of the memory cells of the identified page are in the same state when a read voltage is applied to the page. For example, all or substantially all of the memory cells associated with the identified page may be read or otherwise identified as being in an erased state such that the memory cells have a value of “1”. In another example, all or substantially all of the memory cells associated with the identified page may be read or otherwise identified as being in a programmed state such that the memory cells have a value of “0”. Although specific examples are given, the state of the memory cells may be based on the read voltage that is applied to each of the memory cells.

Once the identified page has been programmed or erased, a “special” read threshold voltage is determined. This read threshold voltage is a read voltage or a sense voltage that, when applied to the memory cells of the identified page during a soft read operation or a soft sensing operation, causes approximately half (e.g., approximately fifty percent, approximately forty-nine percent, approximately forty-five percent) of the memory cells of the identified page to be read as having the opposite state (e.g., based on the special read threshold voltage).

For example, if the memory cells of the identified page are initially in an erased state, the soft read operation or the soft sensing operation performed on the identified page at the read threshold voltage will cause approximately fifty percent of the memory cells to be sensed/read as in, or as being in, a programmed state (e.g., read as “0” when the actual value of a particular memory cell is “1”). Likewise, if the memory cells of the identified page are initially in a programmed state, the soft read operation or the soft sensing operation performed on the page at the read threshold voltage will cause approximately fifty percent of the memory cells to be sensed/read as in, or as being in, an erased state (e.g., read as “1” when the actual value of a particular memory cell is “0”). In some examples, the read threshold voltage is based on PUF values or characteristics (e.g., process, voltage and/or temperature characteristics) associated with the memory die containing or otherwise associated with the identified page, the memory block containing or otherwise associated with the identified page and/or the identified page.

In some examples, a trial and error process or brute force process may be used to determine the read threshold voltage that causes approximately half of the memory cells of the identified page to be read as having the opposite state. For example, a first read threshold voltage is selected or otherwise identified and a soft read operation or a soft sense operation is performed using the first read threshold voltage. Depending on a determined distribution of 1's and 0's that are read from the identified page using the first read threshold voltage, a second read threshold voltage may be determined and the process may repeat.

Once an actual or final read threshold voltage is determined (e.g., a read threshold voltage that causes approximately half of the memory cells of the identified page to be read as having the opposite state), a read or sense operation is performed on the identified page using the actual read threshold voltage. In an example, the read operation or the sense operation causes the data, or other output, associated with the identified page to be provided on an internal ledger of the non-volatile memory device. This raw data may be used to generate a true random number or may otherwise be provided to a controller or other requesting computing device.

For example, the read or sense operation produces a string of bits, or other output, that represents a true random number. Each index of the string of bits is either a “1” or a “0” depending on the actual/final read threshold voltage and the PUF associated with the identified page. Once the string of bits or the random number is sensed/read, the identified page (or a portion of the identified page) and/or the string of bits may be provided to a controller or other computing device associated with the non-volatile memory.

The operations described herein may be used for a variety of different reasons including, but not limited to, the generation of a true random numbers including the generation of several true random numbers at the same time (e.g., a single sense operation on a 16 KB page can generate 512 256-bit true random numbers); the generation of secure cryptographic keys; and/or the generation of unique identifiers for various computing devices and/or semiconductor devices.

In some examples, only the address of the identified page is stored by the non-volatile memory device-not the random number that is generated by the operations. Further, additional hardware and/or circuitry is not used to generate the random number as is typically used by other PUF implementations. As such, the present application provides many technical benefits including, but not limited to, increasing the security of semiconductor devices and/or computing devices because the random number is not discoverable by a would-be attacker or other outside source; reducing and/or eliminating the need for additional hardware on the silicon to generate a random number; and ensuring that the generated random number is a true random number.

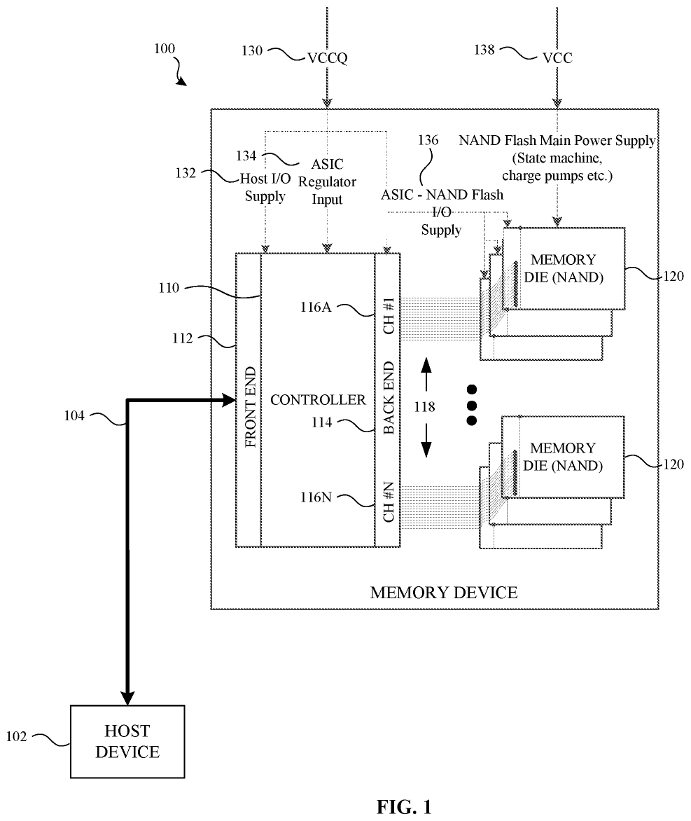

These various benefits and examples will be described in greater detail below with reference to FIG. 1-FIG. 8.

FIG. 1 is a component diagram of an example memory device 100 that may be used to generate a true random number according to an example. In this example, the memory device 100 includes a controller 110 (e.g., an application-specific integrated circuit (ASIC)) and one or more memory dies 120 (e.g., utilizing NAND-type flash memory or such). The controller 110 manages input/output (I/O) operations between the memory device 100 and a host device 102 (e.g., a computing device such as, for example, a mobile phone, a desktop computer, a server computing device, a removable storage card, or the like).

The controller 110 includes a front end module (or just “front end”) 112 that is configured to broker various communication operations between the host device 102 and the memory device 100 (e.g., receiving I/O commands from the host device 102, transmitting associated responses, and the like). The controller 110 also includes a back end module (or just “back end”) 114 that is configured to communicate with the various memory dies 120 included in the memory device 100. The controller 110 may also be responsible for various maintenance operations.

In this example, the memory dies 120 are non-volatile, NAND-type flash memory devices that store and retrieve host data (also referred to herein as “user data”). These memory dies 120 may include 2D or 3D (e.g., stacked) NAND non-volatile memory (e.g., as a 2D or 3D array of memory cells) that define a memory structure that is addressable by word lines using a decoder (e.g., row decoder) and by bit lines. Commands and data are transferred between the host device 102 and the controller 110 using a host interface 104 such as, for example a data bus, a eMMC, UFS, PCIe and the like. Additionally, commands and data may be transferred between the controller 110 and one or more of the memory dies 120 by way of lines 118 (e.g., NAND I/F). For example, a first line or set of lines 118 may be associated with a first channel (e.g., Channel 1 116A) while a second line or set of lines 118 may be associated with a second channel (e.g., Channel N 116N). In one example, memory die 120 includes a set of input and/or output (I/O) pins that connect to lines 118.

The memory device 100 is powered by two power input lines, an I/O voltage (or VCCQ) 130 and a core voltage (or VCC) 138. The VCCQ 130 is used to provide a host I/O Supply 132, an ASIC Regulator Input 134, and an ASIC-NAND Flash I/O supply 136 to the controller 110. The VCC 138 provides a main power supply to the memory dies 120. In some examples, other connections are possible. For example, the core voltage VCC 138 may be received and an internal regulator may transform VCC voltage to I/O voltage and supply the voltage to various memory dies 120. In some examples, VCCQ 130 and/or VCC 138 are provided by the host device 102, which may as such, control power to the memory device 100.

In an example, the controller 110 logically organizes the NAND memory (e.g., all of the bits provided by cells of the memory dies 120) into memory blocks of a predetermined size (e.g., 4 megabytes (MBs), 16 MBs, 32 MBs, or the like). Each of these blocks includes multiple pages of a predetermined page size (e.g., 8 KBs, 16 KBs, 32 KBs, 64 KBs, or the like), where all of the bits/cells for a particular page are all of the cells of a particular wordline.

Such cells can be single-level cells (SLCs) (e.g., storing one bit per cell) or multi-level cells (MLCs) (e.g., storing more than one bit per cell). In an example, a page is the smallest area of the memory dies 120 that supports a write operation and a write operation may be performed on all of the memory cells on a particular wordline. However, partial page programming (e.g., in 4 KB chunks) may also be used. A block is the smallest area of the memory dies 120 that supports an erase operation. In an example, all properly erased bits store a value of “1” after the erase when a “normal” read voltage (e.g., a read voltage that used to read actual stored data) is used.

During operation, the memory device 100 receives I/O commands from the host device 102, such as read commands (e.g., commands for data already stored on the memory device 100), write commands (also sometimes referred to herein as “program commands” or “programming operations”) (e.g., commands to write data to the memory device 100), and erase commands (e.g., commands to erase portions of data currently stored on the memory device 100), amongst others. The memory device 100, namely the controller 110, responds to each of these commands via subsequent operations conducted on the memory dies 120.

In an example, when a random number is to be generated (e.g., in response to a request received by the host device 102 and/or a command received by or otherwise provided by the controller 110) the non-volatile memory PUF (e.g., PUF characteristics and/or PUF values) may be used to generate the random number.

The process of generating a true random number begins when a page of a particular memory die 120 is identified. Once the page is identified, an address (e.g., a physical address) of the identified page is stored by the memory device 100. In an example, the address of the identified page is stored in a memory block and/or memory die 120 that is different from the memory block and/or memory die 120 that stores the identified page. For example, if the identified page is stored or otherwise associated with a first memory block on a first memory die, the address of the identified page may be stored on a second block of the first memory die or on a first memory block of a second memory die.

In another example, the address of the identified page may be stored in the same memory block (e.g., the first memory block) and/or on the same memory die (e.g., the first memory die), but on a different page. For example, a memory block may be erased. As such, all pages of the memory block are in an erased state. Programming of the memory block may commence page by page until a particular page is reached. The particular page may be left empty (e.g., in the erased state) and programming may resume on a page after the particular page. As such, the particular page is effectively set aside for random number generation. The same may also occur during a page programming operation (e.g., one in which all cells are programmed to have the same state).

The controller 110 may also cause an erase operation or a program operation to be performed on the identified page. In an example, the erase operation causes all (or substantially all) of the memory cells associated with the identified page to be in the erased state (e.g., store a value of “1”). Likewise, the program operation causes all (or substantially all) of the memory cells associated with the identified page to be in the programmed state (e.g., store a value of “0”).

In the example described above, all or substantially all of the memory cells associated with the identified page are in the same state. However, it is contemplated that in order to proceed with the generation of a true random number, a first plurality of memory cells may be in a first state. For example, ninety-five percent of the memory cells of the identified page may be in the first state (e.g., a programmed state or an erased state). In another example, ninety-eight percent of the memory cells of the identified page may be in the first state. Although specific percentages are given, these are for example purposes only. However, in order to increase the randomness of the generated number, a substantial majority of the memory cells should be in the first state. Once the identified page has been programmed or erased such as previously described, the controller 110 may determine an initial read threshold voltage that will be used by a soft read operation, a soft sense operation, or a scanning operation. The initial read threshold voltage is a read voltage or a sense voltage that, when applied to the memory cells of the identified page during a “special” soft read operation or a soft sensing operation, causes approximately half of the memory cells of the identified page to be read as having the opposite state. A special read operation or a soft read operation is one in which a read voltage is selected such that the distribution of 1's and 0's is approximately fifty percent or approximately between forty-five percent and fifty-five percent. In another example, a “normal” read operation is one in which a voltage is selected to be as far as possible from a distribution state (e.g., a valley between distributions). For example, a normal read operation is a read operation that is typically executed to read data that has been stored by a page.

For example and as previously described, if the memory cells of the identified page are initially in an erased state, the soft read operation performed on the identified page with the initial read threshold voltage will cause approximately fifty percent of the memory cells to be sensed/read as in a programmed state (e.g., read as “0” when the actual stored value of a particular memory cell is “1”). Likewise, if the memory cells of the identified page are initially in a programmed state, the soft read operation performed on the identified page at the read threshold voltage will cause approximately fifty percent of the memory cells to be sensed/read as in an erased state (e.g., read as “1” when the actual stored value of a particular memory cell is “0”).

Based on the completion of the soft read operation using the initial read threshold voltage, the memory device 100 may initiate an actual or final read threshold voltage determination process. In an example, the read threshold voltage determination process may be a trial and error process or a brute force process.

For example, once the first or initial read threshold voltage is identified or otherwise generated, the first read threshold voltage is applied to the memory cells of the identified page. The memory cells may be scanned, read or otherwise sensed using the first read threshold voltage to determine how the first or initial read threshold voltage affects a distribution of 1's and 0's that are read or otherwise sensed from the identified page. For example, the scan, read or sense operation may be used to determine how many of the bits associated with each of the memory cells of the identified page will be read as having the opposite state (e.g., read as “0” when the actual value of a particular memory cell is “1” or read as “1” when the actual value of a particular memory cell is “0”).

If the distribution of 1's and 0's is approximately fifty percent, the first read threshold voltage is set as the actual or final read threshold voltage. The controller 110 may then cause a subsequent sense or read operation to be performed on the identified page using the actual or final read threshold voltage. In another example, if the distribution of 1's and 0's is approximately fifty percent, a subsequent page read is not required as the random number has already been determined using the first read threshold voltage.

In an example, the read or sense operation may cause the raw data associated with the identified page to be provided on an internal ledger of the memory device 100. The raw data (that represents the true random number) may then be provided to the controller 110 or other requesting computing device and/or circuitry. As indicated above, once the random number is generated, it may be used by the memory device 100 (and/or the host device 102), but it is not stored by the memory device 100. Only the address of the identified page is stored.

For example, when the random number is generated for a one time use, the address of the page may be stored so as to not use the page again. However, if the random number will be used multiple times, the address of the page may be stored in order to locate the page for key construction (e.g., cryptography key generation). If the random number will be used multiple times, parity bits may be generated, stored and/or otherwise associated with the page.

In an example, the randomness of the generated number is based, at least in part, on the memory device PUF (e.g., values or characteristics associated with the memory die 120 on which the identified page is stored, values or characteristics associated with the memory block on which the identified page is stored and/or on values or characteristics associated with the identified page itself). The randomness of the generated number may also be based, at least in part, on the determined read threshold voltage (e.g., actual or final read threshold voltage). For example, a bit in a particular memory cell of the identified page may be read/sensed as having flipped from one state to another based on the determined read threshold voltage.

Referring back to the example above, if it is determined that the first read threshold voltage does not cause the distribution of 1's and 0's to be approximately fifty percent, a second read threshold voltage is determined, generated or otherwise identified. In an example, the controller 110 intelligently determines the value of the second read threshold voltage based, at least in part, on the first read threshold voltage, the first state of the memory cells in the identified page and/or the determined distribution of 1's and 0's caused by the first read threshold voltage.

For example, if the identified page is in an erased state and the first read threshold voltage caused twenty-five percent of the memory cells associated with the identified page to be read as being in a programmed state, the controller 110 may determine that the second read threshold voltage should be greater than the first read threshold voltage. However, if the identified page is in an erased state and the first read threshold voltage caused seventy-five percent of the memory cells associated with the identified page to be read as being in a programmed state, the controller 110 may determine that the second read threshold voltage should be less than the first read threshold voltage. This process (e.g., the determination of different read threshold voltages) may be repeated N number of times until an appropriate or final read threshold voltage (e.g., a read threshold voltage that causes the distribution of 1's and 0+s in the memory cells of the identified page to be approximately fifty percent) is determined or otherwise identified.

If the distribution of 1's and 0's is approximately fifty percent, the Nth read threshold voltage is set as the actual/final read threshold voltage. The controller 110 may then cause a subsequent sense or read operation to be performed on the identified page using the actual/final read threshold voltage such as described above. In another example, the controller 110 may simply use the last sensed page with the approximate fifty percent distribution.

Using the operations described above, a value (e.g., a “1” or a “0”) that is read from each memory cell associated with the identified page will be truly random. For example, memory cell j and memory cell j+1 associated with the identified page may each have a value of “1” prior to the first read threshold voltage being applied to the identified page. However, when the first read threshold voltage is used by a soft read operation, memory cell j and may be read as having a value of “1” while memory cell j+1 may be read as having a value of “0”. Likewise, when the second read threshold voltage is applied to the identified page (e.g., as part of a soft read operation), memory cell j and may be read as having a value of “0” while memory cell j+1 may be read as having a value of “1”.

Thus, as different read threshold voltages are applied to the memory cells of the identified page, the values that are read may change. As previously explained, this is due to the PUF values or characteristics (e.g., process, voltage and/or temperature characteristics) associated with the memory die.

In an example, the size of the identified page is 16 KB. As such, and in order to generate a true random number, approximately 8 KB of the identified page may be read as being in a first state while approximately 8 KB of the identified page may be read as being in a second state that is opposite from or otherwise different than the first state. Thus, the identified page will generate a 16 KB string or other such output that represents a true random number. While a 16 KB page is specifically disclosed, one or more portions of the identified page may be used to generate the true random number.

For example, 4 KBs of the identified page may be used to generate the random number using the operations described above. In another example, 8 KBs of the identified page may be used to generate the random number using the operations described above. In such examples, the distribution of 1's and 0's for the portion of the page may need to be approximately fifty percent such as previously described in order to generate the true random number. When a portion of the identified page is used to generate the random number, only the portion of the identified page that was used may be transferred to the controller 110.

Although a 16 KB string is mentioned above, a single identified page may be used to generate a single random number or multiple different random numbers at the same time. For example, a 16 KB page contains 131,072 bits. If the entire identified page is used to generate a random number, one sense operation may be used to generate 512 256-bit random numbers. In another example, the true random number may be used to generate secure cryptographic keys. In one example, a single 16 KB page can contain 512 AES 256-bit keys or 32 RSA 4096 bits keys.

In order to generate secure cryptographic keys, the true random number may be generated in the manner described above. Once the true random number has been generated, the address of the identified page is stored in the memory device 100. Additionally, parity bits associated with the true random number may be generated and stored in the memory device 100. The parity bits may be stored in any location within the memory device. The true random number may be used to generate a secure key.

In order to subsequently utilize the key, the address of the identified page is retrieved, programmed or erased (such as previously described) and subsequently sensed with an appropriate read voltage threshold (e.g., the same or similar read voltage threshold that was used to initially generate the true random number). The data associated with the identified page (or the page itself) may be transferred to a controller or other requesting computing device. Due to expected variance during the lifetime of the memory device 100, the parity bits may be retrieved and used to correct any errors in the reproduced random number. The reproduced random number may then be used to decode the cryptographic key. In some examples, since correction capabilities are available, the operation(s) of finding the read threshold voltage may be omitted.

In some examples, the process described above enhances security features of cryptographic keys as an outside observer has to know the read threshold voltage that was used to read the identified page. In addition, the identified page will not include any indication that the identified page is used for random number generation as it will either be fully erased or fully programmed. Even if the outside observer knows the read threshold voltage, it must correct the read value to the exact values used in first place. In order to determine this, the outside observer must know where parity bits are stored.

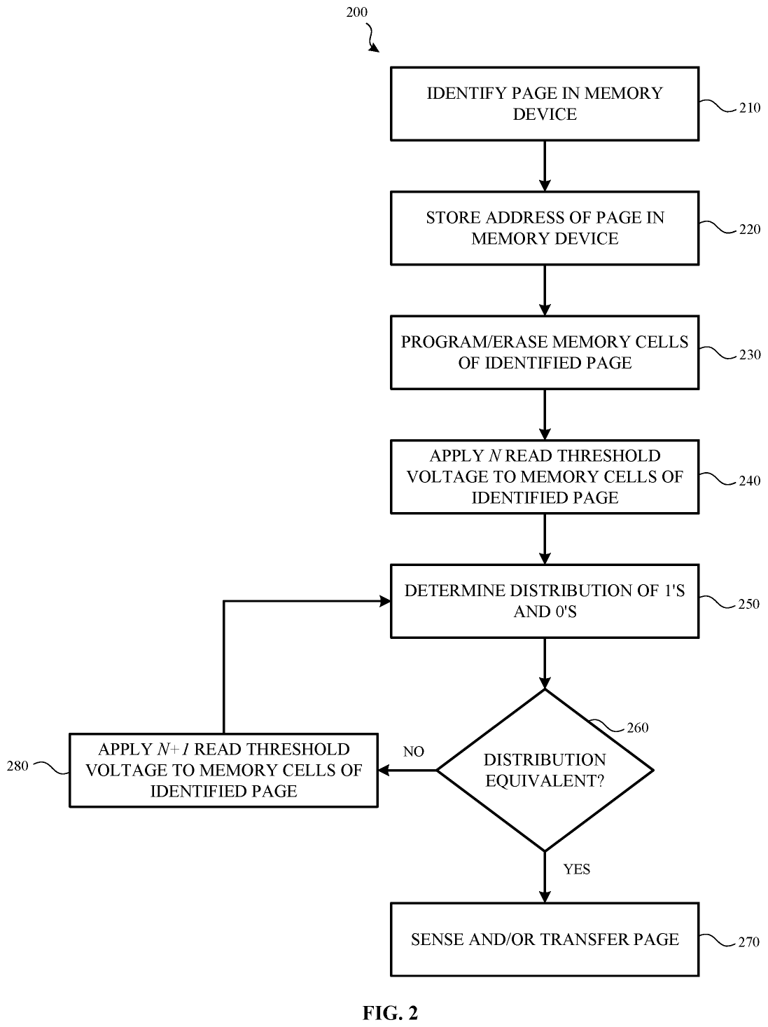

FIG. 2 illustrates a method 200 for using a non-volatile memory based physical unclonable function (PUF) to generate a true random number according to an example. In an example, the method 200 may be performed by the memory device 100 and/or the host device 102 shown and described with respect to FIG. 1.

Method 200 begins when a page in a memory device is identified (210). In an example, the identified page is associated with a particular block of a memory die (e.g., memory die 120). Due to physical manufacturing variations of the non-volatile memory (and/or due to the physical manufacturing variations of the memory die associated with the identified page, the memory block associated with the identified page and/or with the identified page itself), the identified page may respond in a unique and unclonable way to a given input (e.g., a read voltage threshold). For example, due to process, voltage and/or temperature characteristics and/or properties associated with the identified page, when a particular read voltage threshold is applied to the identified page, a true random number may be generated.

Once the page has been identified, an address of the identified page is stored (220) in the memory device. In some examples, the address of the identified page is stored in a memory block and/or in a memory die that is different than the memory block and/or memory die in which the identified page is stored. In other examples, the address of the identified page may be stored in the same memory block and/or in the same memory die as the identified page.

The block associated with the identified page may be erased, thereby erasing each page associated with the block. The identified page may then be programmed or erased (230) such as described above. For example, a controller of the system may determine whether a pass status has been received upon completion of a program or erase operation. As previously described, during a normal read, the memory cells associated with the identified page may be in an erased state such that the memory cells have a value of “1” or may be in a programmed state such that the memory cells have a value of “0”.

Once the identified page has been programmed or erased, a N (e.g., a first) read threshold voltage is determined or otherwise identified and applied (240) to the memory cells of the identified page. In an example, the N read threshold voltage may be randomly determined or otherwise selected. As the method 200 continues, the N read threshold voltage may be intelligently adjusted based, at least in part, on the resulting/determined distributions of read 1's and 0's of the memory cells of the identified page.

In an example, applying the N read threshold voltage may include performing a soft read operation, a soft sense operation or a soft scanning operation on the identified page to determine (250) how the N read threshold voltage will affect a distribution of 1's and 0's that are read from the identified page during the soft read operation. For example, if the memory cells of the identified page are initially in an erased state, the N read threshold voltage used by the soft read operation may cause X memory cells to be sensed/read as being in a programmed state. Likewise, if the memory cells of the identified page are initially in a programmed state, the N read threshold voltage used by the soft read operation may cause Y memory cells to be sensed/read as being in an erased state.

In an example, the distribution of 1's and 0's may be determined for the entire identified page (e.g., the entire 16 KB page) or for a portion of the identified page. In examples in which the distribution of 1's and 0's for the portion (e.g., 8 KBs) of the page is determined, it may be presumed that the distribution of 1's and 0's for the rest of the identified page has a similar distribution of 1's and 0's.

Once the distribution of 1's and 0's is determined, a determination (260) is made as to whether the distribution of 1's and 0's is equivalent or substantially equivalent. In some examples, the distribution of 1's and 0's may be equivalent or substantially equivalent when approximately half of the memory cells of the identified page are read, sensed or are otherwise identified (using the “special” read voltage threshold) as being in a first state (e.g., a “1”) and when approximately half of the memory cells of the identified page are read, sensed or are otherwise identified as being in a second state (e.g., a “0”).

In other examples, the distribution of 1's and 0's may be equivalent or substantially equivalent when approximately forty-nine percent of the memory cells of the identified page are read, sensed or are otherwise identified as being in a first state and when approximately fifty-one percent of the memory cell of the identified page are read, sensed or are otherwise identified as being in a second state. Although specific ranges are given, other ranges may be used. For example, the distribution of 1's and 0's may be equivalent or substantially equivalent when approximately forty-five percent of the memory cells of the identified page are read, sensed or are otherwise identified as being in a first state and when approximately fifty-five percent of the memory cell of the identified page are read, sensed or are otherwise identified as being in a second state.

If it is determined (260) that the distribution of 1's and 0's of the identified page is equivalent or substantially equivalent, a sense operation may subsequently be performed. In some examples, the subsequent sense operation may be optional depending on whether the entire identified page was read using the soft sense operation.

In an example, the subsequent read or sense operation is performed using the N read threshold voltage. The read or sense operation produces a string of bits that represents a true random number. For example, each index of the string of bits is either a “1” or a “0” depending on the read threshold voltage and the PUF characteristics associated with the identified page. Once the string of bits or the random number is sensed/read, the identified page (or a portion of the identified page) and/or the string of bits is transferred (270) or otherwise provided to a controller (e.g., controller 110 (FIG. 1)) or other computing device associated with the non-volatile memory.

However, if it is determined (260) that N read threshold voltage that is applied to the identified page does not cause the distribution of 1's and 0's to be equivalent or substantially equivalent, a N+1 read threshold voltage is determined and applied (280) to the memory cells of the identified page using a subsequent soft read operation. In an example, the controller or other processing circuitry associated with the memory device may intelligently determine the value of the N read threshold voltage and/or the N+1 read threshold voltage and so on. The determination may be based, at least in part, on the first read threshold voltage, the first state of the memory cells in the identified page and/or the determined distribution of 1's and 0's caused by the N read threshold voltage.

For example, if the identified page is initially in an erased state and the first read threshold voltage caused twenty-five percent of the memory cells associated with the identified page to be read as being in a programmed state, the controller 110 may determine that the second read threshold voltage should be greater than the first read threshold voltage. However, if the identified page is in an erased state and the first read threshold voltage caused seventy-five percent of the memory cells associated with the identified page to be read as being in a programmed state, the controller may determine that the second read threshold voltage should be less than the first read threshold voltage.

Once the N+1 read threshold voltage is applied to the memory cells of the identified page, the distribution of read 1's and 0's is determined (250) such as described above. The various operations may be repeated any number of times until the read distribution of 1's and 0's is equivalent or substantially equivalent and a final/actual read threshold voltage is determined and subsequently used to generate the true random number.

Using the process described above, a true random number may be generated. For example, in the identified page, memory cell j and memory cell j+1 may each have an initial value of “1”. When the N read threshold voltage is used or otherwise applied to the identified page as part of a soft read operation, memory cell j and may be read as having a value of “1” while memory cell j+1 may be read as having a value of “0”. Likewise, when the N+1 read threshold voltage is used or otherwise applied to the identified page as part of a soft read operation, memory cell j and may be read as having a value of “0” while memory cell j+1 may be read as having a value of “1”. Thus, as different read threshold voltages are applied to the memory cells of the identified page, the resulting read value may change.

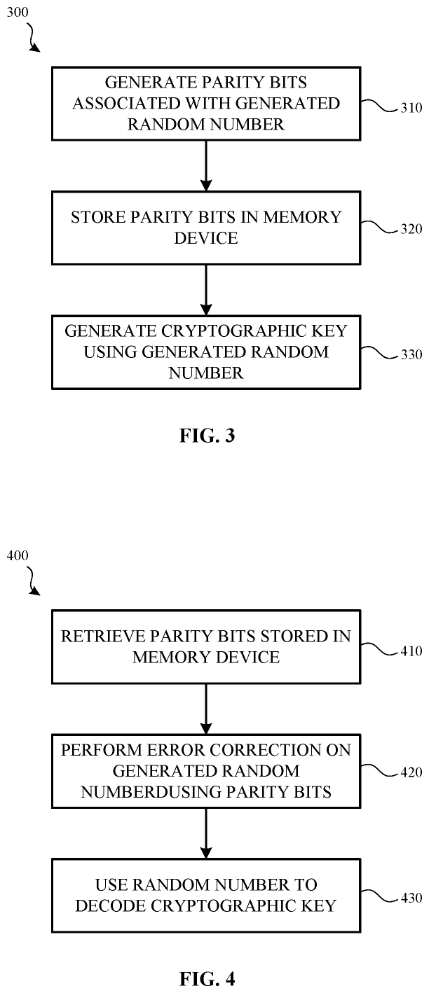

FIG. 3 illustrates a method 300 for using a true random number to generate a cryptographic key according to an example. In some examples, one or more operations of the method 300 may be performed in conjunction with one or more operations of method 200 shown and described with respect to FIG. 2. For example, method 300 may be performed in response to operation 270 being performed.

As briefly discussed, in order to generate secure cryptographic keys, a true random number may be generated. Once the true random number has been generated, parity bits associated with the true random number may be generated (310). In an example, the parity bits may be generated in any suitable fashion.

Once the parity bits have been generated, the parity bits are stored (320) in a memory device (e.g., memory device 100 (FIG. 1)). In some examples, the parity bits are stored in a memory block and/or in a memory die that is different than the memory block and/or memory die in which the identified page (e.g., the page that was initially used to generate the true random number) is stored. Once the parity bits have been generated and subsequently stored, the true random number may be used to generate (330) a cryptographic key.

FIG. 4 illustrates a method 400 for reproducing true random number to decode a cryptographic key according to an example. In some examples, one or more operations of the method 400 may be performed in conjunction with one or more operations of method 200 shown and described with respect to FIG. 2. For example, method 400 may be performed in response to operation 270 being performed.

For example, and in order to subsequently utilize the cryptographic key, the address of the initial identified page is retrieved. The initial identified page may then be read with an appropriate read voltage threshold (e.g., the same or similar read voltage threshold that was used to initially generate the true random number). If the distribution of 1's and 0's is not approximately fifty percent using the same read voltage threshold, the read voltage threshold may be adjusted until the appropriate (e.g., fifty percent) distribution is found.

The data associated with the identified page (or the page itself) may be transferred to a controller or other requesting computing device. Due to expected variance during the lifetime of the memory device, parity bits (e.g., parity bits that were generated in operation 310 (FIG. 3)) may be retrieved (410) and used to correct (420) any errors in the reproduced random number. The random number, along with parity bits may be used together (e.g., by an error correcting code engine) to decode (430) the cryptographic key.

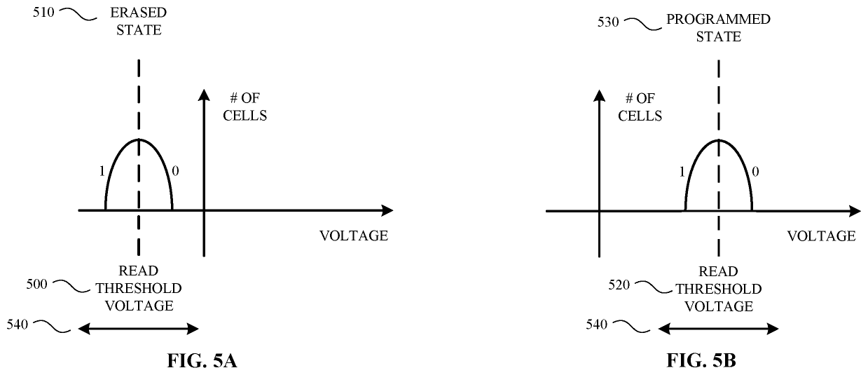

FIG. 5A illustrates an example read threshold voltage 500 that may be adjusted based on a determined distribution of 1's and 0's when an identified page of a memory die of a non-volatile memory device has been set to an erase state 510 according to an example and FIG. 5B illustrates an example read threshold voltage 520 that may be adjusted based on a determined distribution of 1's and 0's when an identified page of a memory die of a non-volatile memory device has been set to a programmed state 530 according to an example.

For example and as shown in FIG. 5A, a controller (e.g., controller 110 (FIG. 1)) associated with a memory device (e.g., memory device 100 (FIG. 1)) may identify a page of a memory die (e.g., memory die 120 (FIG. 1)) and cause the identified page to be in a first state (e.g., an erased state 510) in which all or substantially all of the memory cells associated with the page are set to “1”.

An initial read threshold voltage 500 be determined. The initial read threshold voltage 500 may be used by a soft read operation to determine a distribution of read 1's and 0's. Based on the determined distribution of read 1's and 0's, the read threshold voltage 500 may be adjusted (either increased or decreased represented by arrow 540). The process may repeat until the read distribution of 1's and 0's is substantially equivalent.

Likewise, and as shown in FIG. 5B, the controller may identify a page of the memory die and cause the identified page to be in a first state (e.g., a programmed state 530) in which all or substantially all of the memory cells associated with the page are set to “0”. An initial read threshold voltage 520 may be determined. The initial read threshold voltage 520 may be used by a soft read operation to determine a distribution of read 1's and 0's. Based on the determined distribution of read 1's and 0's, the initial read threshold voltage 520 may be either increased or decreased represented by arrow 540 such as previously described.

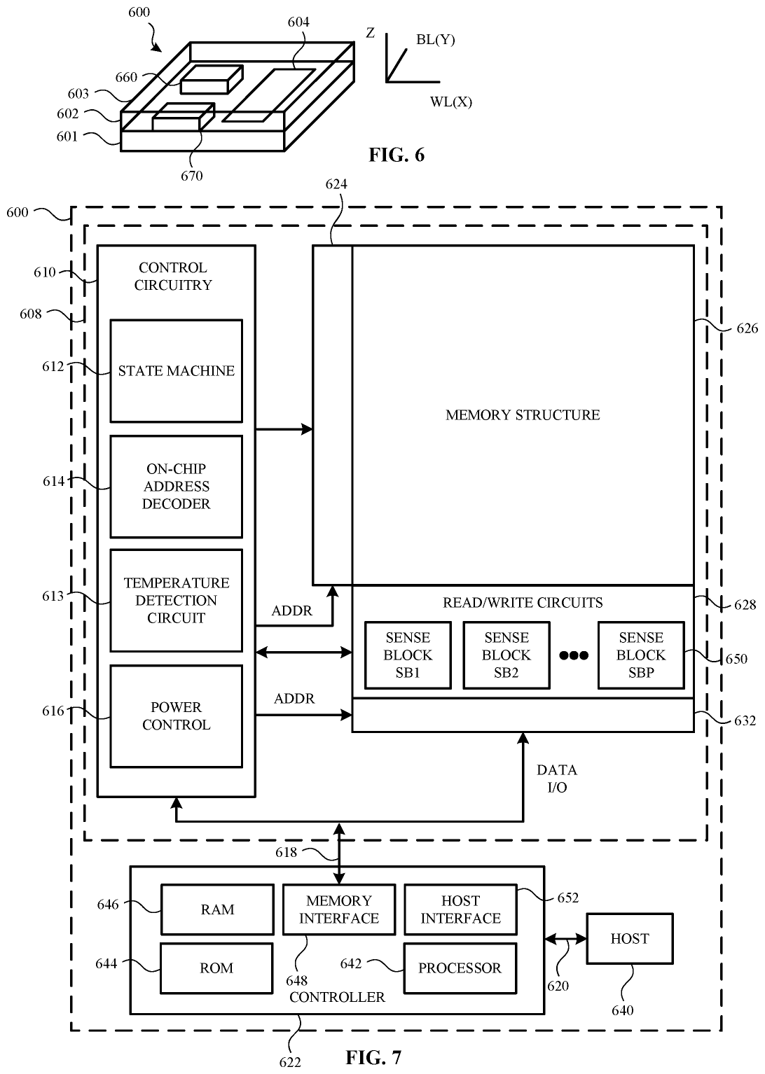

FIG. 6-FIG. 8 describe an example storage system that may be similar to the memory device 100 of FIG. 1, components of which may implement the various methods described herein. In some examples, the controller 622 is similar to the controller 110 of FIG. 1 and the memory dies 608 are similar to the memory dies 120 of FIG. 1. FIG. 6 is a perspective view of a storage device 600 that includes three-dimensional (3D) stacked non-volatile memory according to an example. The storage device 600 includes a substrate 601. On and above the substrate are example blocks of memory cells, including a first block (BLK0 660) and a second block (BLK1 670), formed of memory cells (non-volatile memory elements). Also on substrate 601 is peripheral area 604 with support circuits for use by the blocks. Substrate 601 can also carry circuits under the blocks, along with one or more lower metal layers which are patterned in conductive paths to carry signals of the circuits. The blocks are formed in an intermediate region 602 of the storage device 600. In an upper region 603 of the storage device 600, one or more upper metal layers are patterned in conductive paths to carry signals of the circuits. Each block of memory cells includes a stacked area of memory cells, where alternating levels of the stack represent word lines. While two blocks are depicted as an example, additional blocks can be used, extending in the x-direction and/or the y-direction.

In one example implementation, the length of the plane in the x-direction represents a direction in which signal paths for word lines extend (e.g., a word line or drain-end select gate (SGD) line direction) and the width of the plane in the y-direction represents a direction in which signal paths for bit lines extend (e.g., a bit line direction). The z-direction represents a height of the storage device 600.

FIG. 7 is a functional block diagram of a storage device 600 according to an example. In one example, the storage device 600 may be the 3D stacked non-volatile storage device 600 shown in FIG. 6. The components depicted in FIG. 7 are electrical circuits. Storage device 600 includes one or more memory dies 608. Each memory die 608 includes a three-dimensional memory structure 626 of memory cells (e.g., a 3D array of memory cells), control circuitry 610, and read/write circuits 628. In other examples, a two-dimensional array of memory cells can be used. Memory structure 626 is addressable by word lines using a decoder 624 (e.g., row decoder) and by bit lines using a column decoder 632. The read/write circuits 628 include multiple sense blocks 650 including SB1, SB2, . . . , SBp (e.g., sensing circuitry) and allow a page of memory cells to be read or programmed in parallel.

In some systems, the controller 622 is included in the same storage device 600 (e.g., a removable storage card) as the one or more memory dies 608. In some examples, the controller 622 is formed on a die that is bonded to a memory die, in which case each memory die has its own controller. In other examples, a controller die controls all of the memory dies. Commands and data are transferred between a host 640 and the controller 622 using a data bus 620, and between controller 622 and one or more of the memory dies 608 by way of lines 618. In one example, memory die 608 includes a set of input and/or output (I/O) pins that connect to lines 618.

Memory structure 626 may include one or more arrays of memory cells, including a 3D array. The memory structure may include a monolithic 3D memory structure in which multiple memory levels are formed above (e.g., and not in) a single substrate, such as a wafer, with no intervening substrates. The memory structure may include any type of non-volatile memory that is monolithically formed in one or more physical levels of arrays of memory cells having an active area disposed above a silicon substrate. The memory structure may be in a non-volatile memory device having circuitry associated with the operation of the memory cells, whether the associated circuitry is above or within the substrate.

Control circuitry 610 cooperates with the read/write circuits 628 to perform memory operations (e.g., erase, program, read, and others) on memory structure 626, and includes a state machine 612, an on-chip address decoder 614, and a power control module 616. The state machine 612 provides chip-level control of memory operations. Temperature detection circuit 613 is configured to detect temperature, and can be any suitable temperature detection circuit. In one example, state machine 612 is programmable by software. In other examples, state machine 612 does not use software and is completely implemented in hardware (e.g., electrical circuits). In one example, control circuitry 610 includes registers, ROM fuses, and other devices for storing default values such as base voltages and other parameters.

The on-chip address decoder 614 provides an address interface between addresses used by host 640 or controller 622 to the hardware address used by the decoders 624 and 632. Power control module 616 controls the power and voltages supplied to the word lines and bit lines during memory operations. It can include drivers for word line layers in a 3D configuration, select transistors (e.g., SGS and SGD transistors) and source lines. Power control module 616 may include charge pumps for creating voltages. The sense blocks include bit line drivers. An SGS transistor is a select gate transistor at a source end of a NAND string, and an SGD transistor is a select gate transistor at a drain end of a NAND string.

Any one or any combination of control circuitry 610, state machine 612, decoders 614/624/632, temperature detection circuit 613, power control module 616, sense blocks 650, read/write circuits 628, and controller 622 can be considered one or more control circuits, or a managing circuit, that performs some or all of the functions described herein.

Controller 622, which in one example is an electrical circuit that may be on-chip or off-chip, may include one or more processors 642, ROM 644, RAM 646, memory interface 648, and host interface 652, all of which are interconnected. One or more processors 642 is one example of a control circuit. Other examples can use state machines or other custom circuits designed to perform one or more functions. Devices such as ROM 644 and RAM 646 may include code such as a set of instructions, and the processor 642 may be operable to execute the set of instructions to provide some or all of the functionality described herein. Alternatively or additionally, processor 642 may access code from a memory device in the memory structure 626, such as a reserved area of memory cells connected to one or more word lines. Memory interface 648, in communication with ROM 644, RAM 646, and processor 642, is an electrical circuit that provides an electrical interface between controller 622 and memory die 608. For example, memory interface 648 can change the format or timing of signals, provide a buffer, isolate from surges, latch I/O, and so forth.

Processor 642 may issue commands to control circuitry 610, or any other component of memory die 608, using memory interface 648. Host interface 652, in communication with ROM 644, RAM 646, and processor 642, is an electrical circuit that provides an electrical interface between controller 622 and host 640. For example, host interface 652 can change the format or timing of signals, provide a buffer, isolate from surges, latch I/O, and so forth. Commands and data from host 640 are received by controller 622 by way of host interface 652. Data sent to host 640 is transmitted using data bus 620.

Multiple memory elements in memory structure 626 may be configured so that they are connected in series or so that each element is individually accessible. By way of non-limiting example, flash memory devices in a NAND configuration (e.g., NAND flash memory) typically contain memory elements connected in series. A NAND string is an example of a set of series-connected memory cells and select gate transistors.

A NAND flash memory array may be configured so that the array includes multiple NAND strings, where a NAND string includes multiple memory cells sharing a single bit line and that are accessed as a group. Alternatively, memory elements may be configured so that each element is individually accessible (e.g., a NOR memory array). NAND and NOR memory configurations are exemplary, and memory cells may be otherwise configured.

The memory cells may be arranged in the single memory device level in an ordered array, such as in a plurality of rows and/or columns. However, the memory elements may be arrayed in non-regular or non-orthogonal configurations, or in structures not considered arrays.

Some three-dimensional memory arrays are arranged so that memory cells occupy multiple planes or multiple memory device levels, thereby forming a structure in three dimensions (e.g., in the x, y, and z directions, where the z direction is substantially perpendicular and the x and y directions are substantially parallel to the major surface of the substrate).

As a non-limiting example, a 3D memory structure may be vertically arranged as a stack of multiple 2D memory device levels. As another non-limiting example, a 3D memory array may be arranged as multiple vertical columns (e.g., columns extending substantially perpendicular to the major surface of the substrate, such as in the y direction) with each column having multiple memory cells. The vertical columns may be arranged in a two-dimensional arrangement of memory cells, with memory cells on multiple vertically stacked memory planes. Other configurations of memory elements in three dimensions can also constitute a 3D memory array.

By way of non-limiting example, in a 3D NAND memory array, the memory elements may be coupled together to form vertical NAND strings that traverse across multiple horizontal memory device levels. Other 3D configurations can be envisioned wherein some NAND strings contain memory elements in a single memory level while other strings contain memory elements which span through multiple memory levels. 3D memory arrays may also be designed in a NOR configuration and in a ReRAM configuration.

A person of ordinary skill in the art will recognize that the technology described herein is not limited to a single specific memory structure, but covers many relevant memory structures within the spirit and scope of the technology as described herein and as understood by one of ordinary skill in the art.

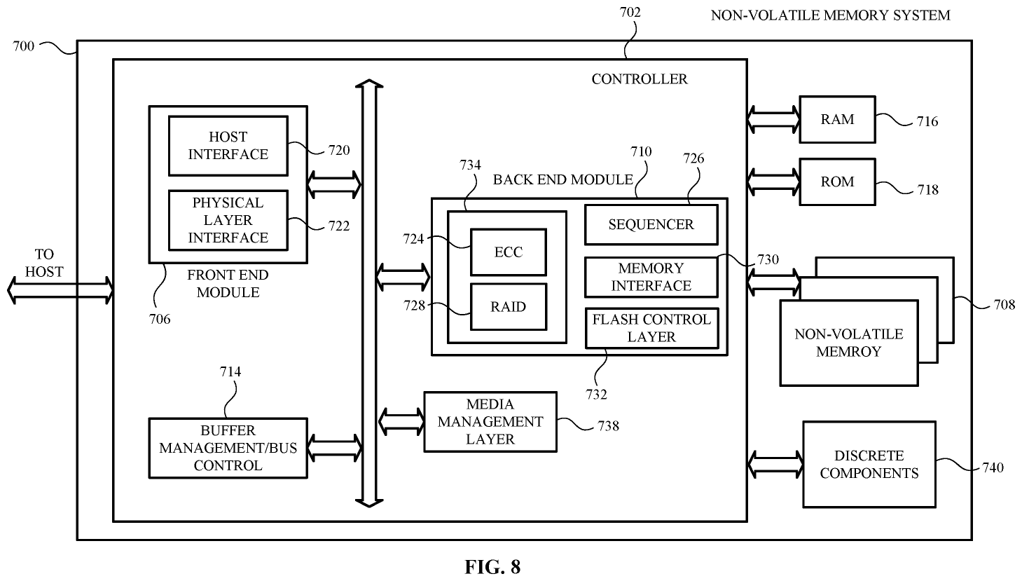

FIG. 8 is another block diagram of a storage device 700 according to an example. The storage device 700 shown and described with respect to FIG. 8 depicts additional details of a controller 702. In an example, controller 702 may be similar to the controller 622 shown an described with respect to FIG. 7. In one example, the system of FIG. 8 is a solid-state drive (SSD). As used herein, a flash memory controller is a device that manages data stored on flash memory and communicates with a host, such as a computer or other electronic device. A flash memory controller may have various functionalities in addition to the specific functionalities described herein.

For example, the flash memory controller may format the flash memory to ensure the memory is operating properly, map out bad flash memory cells, and allocate spare memory cells to be substituted for future failed memory cells. Some part of the spare memory cells can be used to hold firmware to operate the flash memory controller and implement other features. During operation, when a host reads data from or writes data to the flash memory, the host will communicate with the flash memory controller. If the host provides a logical address to which data is to be read/written, the flash memory controller may convert the logical address received from the host to a physical address in the flash memory.

Alternatively, in some examples, the host may provide the physical address. The flash memory controller may also perform various memory management functions such as, but not limited to, wear leveling (e.g., distributing writes to avoid wearing out specific blocks of memory that may otherwise be repeatedly written to) and garbage collection (e.g., after a block is full, moving only the valid pages of data to a new block, so the full block can be erased and reused). Non-volatile memories other than flash may have non-volatile memory controllers that are similar to flash memory controllers.

The communications interface between controller 702 and non-volatile memory dies 708 may be any suitable flash interface, such as toggle mode. In one example, storage device 700 may be a card based system, such as a secure digital (SD) or a micro secure digital (micro-SD) card. In another example, storage system 700 may be part of an embedded storage system. For example, the flash memory may be embedded within the host, such as in the form of a solid-state disk drive installed in a personal computer.

In some examples, storage system 700 includes a single channel between controller 702 and non-volatile memory dies 708. However, the subject matter described herein is not limited to having a single memory channel. For example, in some storage system architectures, two, four, eight, or more channels may exist between the controller and the memory dies 708 (e.g., depending on controller capabilities). In any of the examples described herein, more than a single channel may exist between the controller and the memory dies 708, even if a single channel is shown in the drawings.

As also shown in FIG. 8, the controller 702 includes a front-end module 706 that interfaces with a host, a back-end module 710 that interfaces with the one or more non-volatile memory dies 708, and various other modules that perform functions which are described herein.

The components of controller 702 may take the form of a packaged functional hardware unit (e.g., an electrical circuit) designed for use with other components, a portion of a program code (e.g., software or firmware) executable by processing circuitry that performs a particular function or related functions, or a self-contained hardware or software component that interfaces with a larger system. The controller 702 may include an application-specific integrated circuit (ASIC), a field programmable gate array (FPGA), a circuit, a digital logic circuit, an analog circuit, a combination of discrete circuits, gates, or any other type of hardware or combination thereof. The architecture depicted in FIG. 8 is one example implementation that may or may not use the components of controller 622 depicted in FIG. 7 (e.g., RAM, ROM, processor, interface).

In an example, the controller 702 includes a buffer manager/bus controller 714 that manages buffers in random access memory (RAM) 716 and controls the internal bus arbitration of controller 702. A read-only memory (ROM) 718 stores system boot code. Although illustrated as being separate from the controller 702, in some examples, one or both of the RAM 716 and ROM 718 may be located both within the controller 702 or outside the controller 702. Further, in some implementations, the controller 702, RAM 716, and ROM 718 may be located on separate semiconductor dies.

Front-end module 706 includes a host interface 720 and a physical layer interface 722 that provide the electrical interface with the host or next level storage controller. The choice of the type of host interface 720 can depend on the type of memory being used. Examples of host interfaces 720 include, but are not limited to, SATA, SATA Express, SAS, Fibre Channel, USB, PCIe, and NVMe. The host interface 720 may be a communication interface that facilitates transfer for data, control signals, and timing signals.

Back-end module 710 includes an error correction controller (ECC) engine 724 that encodes the data bytes received from the host and decodes and error corrects the data bytes read from the non-volatile memory. A command sequencer 726 generates command sequences, such as program and erase command sequences, to be transmitted to non-volatile memory dies 708. A RAID (redundant array of independent dies) module 728 manages generation of RAID parity and recovery of failed data.

The RAID parity may be used as an additional level of integrity protection for the data being written into the storage device 700. In some cases, the RAID module 728 may be a part of the ECC engine 724. Note that the RAID parity may be added as an extra die or dies, or may be added within existing dies (e.g., as extra plane(s), extra block(s), or extra WL(s) within block(s). ECC engine 724 and RAID module 728 may calculate redundant data that can be used to recover when errors occur and may be considered examples of redundancy encoders. Together, ECC engine 724 and RAID module 728 may be considered to form a combined redundancy encoder 734. A memory interface 730 provides the command sequences to non-volatile memory die 708 and receives status information from non-volatile memory dies 708. In some examples, memory interface 730 may be a double data rate (DDR) interface. A flash control layer 732 controls the overall operation of back-end module 710.

Additional components of storage device 700 illustrated in FIG. 8 include media management layer 738, which performs wear leveling of memory cells of non-volatile memory dies 708. Storage device 700 also includes other discrete components 740, such as external electrical interfaces, external RAM, resistors, capacitors, or other components that may interface with controller 702. In other examples, one or more of the physical layer interface 722, media management layer 738, and buffer management/bus controller 714 are optional components that are not necessary in the controller 702.

The Flash Translation Layer (FTL) or Media Management Layer (MML) 738 may be integrated as part of the flash management that may handle flash errors and interfacing with the host. In particular, MML may be a module in flash management and may be responsible for the internals of NAND management. In particular, the MML 738 may include an algorithm in the storage device firmware which translates writes from the host into writes to the flash memory structure (e.g., memory structure 626 (FIG. 7)) of a memory die (e.g., memory die 608 (FIG. 6)).

The MML 738 may be used because, for example, the flash memory may have limited endurance, the flash memory structure may only be written in multiples of pages, or the flash memory structure may not be written unless it is erased as a block (e.g., a block may be considered to be a minimum unit of erase and such a non-volatile memory may be considered a block-erasable non-volatile memory). The MML 638 is configured to operate under these potential limitations of the flash memory structure, which may not be visible to the host. Accordingly, the MML 638 attempts to translate the writes from host into writes into the flash memory structure.

The controller 702 may interface with one or more memory dies. In one example, controller 702 and multiple memory dies (e.g., together making up the storage device 700) implement an SSD, which can emulate, replace, or be used instead of a hard disk drive inside a host device, as a NAS device, or the like. Additionally, the SSD need not be made to work as a hard drive.

The term computer-readable media as used herein may include computer storage media. Computer storage media may include volatile and nonvolatile, removable and non-removable media implemented in any method or technology for storage of information, such as computer readable instructions, data structures, or program modules. Computer storage media may include RAM, ROM, electrically erasable read-only memory (EEPROM), flash memory or other memory technology, CD-ROM, digital versatile disks (DVD) or other optical storage, magnetic cassettes, magnetic tape, magnetic disk storage or other magnetic storage devices, or any other article of manufacture which can be used to store information and which can be accessed by a computing device (e.g., host device 102 (FIG. 1)). Any such computer storage media may be part of the computing device. Computer storage media does not include a carrier wave or other propagated or modulated data signal.

Additionally, examples described herein may be discussed in the general context of computer-executable instructions residing on some form of computer-readable storage medium, such as program modules, executed by one or more computers or other devices. By way of example, and not limitation, computer-readable storage media may comprise non-transitory computer storage media and communication media. Generally, program modules include routines, programs, objects, components, data structures, etc., that perform particular tasks or implement particular abstract data types. The functionality of the program modules may be combined or distributed as desired in various examples.

Communication media may be embodied by computer readable instructions, data structures, program modules, or other data in a modulated data signal, such as a carrier wave or other transport mechanism, and includes any information delivery media. The term “modulated data signal” may describe a signal that has one or more characteristics set or changed in such a manner as to encode information in the signal. By way of example, and not limitation, communication media may include wired media such as a wired network or direct-wired connection, and wireless media such as acoustic, radio frequency (RF), infrared, and other wireless media.

In accordance with the above, examples of the present disclosure describe a method for generating a random number using a non-volatile memory based physical unclonable function (PUF), comprising: identifying a page of a memory die of a non-volatile memory device; causing a plurality of memory cells associated with the identified page to be in a first state; determining an initial read threshold voltage; performing a soft read operation on the plurality of memory cells using the initial read threshold voltage, wherein the soft read operation using the initial read threshold voltage causes a subset of memory cells of the plurality of memory cells to be read as being in a second state that is different than the first state; determining whether a number of memory cells being read as being in the second state is substantially equivalent to a number of memory cells being read as being in the first state; based on determining that the number of memory cells being read as being in the second state is substantially equivalent to the number of memory cells being read as being in the first state, generating an output; and providing the output to a requesting computing device.

In an example, the output is a random number represented by the number of memory cells being read as being in the second state and the number of memory cells being read as being in the first state. In an example, the method also includes determining a second read threshold voltage based on determining that the number of memory cells being read as being in the second state is substantially higher or substantially lower than the number of memory cells being read as being in the first state. In an example, the method also includes performing a subsequent soft read operation on the plurality of memory cells using the second read threshold voltage, wherein the subsequent soft read operation using the second read threshold voltage causes a second subset of memory cells of the plurality of memory cells to be read as being in a second state that is different than the first state; and determining whether a second number of memory cells being read as being in the second state is substantially equivalent to a second number of memory cells being read as being in the first state.

In an example, the method also includes based on determining that the second number of memory cells being read as being in the second state is substantially equivalent to the second number of memory cells being read as being in the first state, generating the output; and providing the output to a requesting computing device. In an example, identifying the page of the memory die comprises identifying an address of the identified page. In an example, the method also includes storing the address of the identified page in the non-volatile memory device. In an example, the method also includes generating parity bits associated with the output. In an example, the method also includes storing the parity bits in the non-volatile memory device. In an example, the first state is a state in which the plurality of memory cells are in an erased state. In an example, the first state is a state in which the plurality of memory cells are in a programmed state.

Examples of the present disclosure also describe a data storage device, comprising: at least one memory die; and a controller communicatively coupled to the at least one memory die and configured to: identify a page of the memory die; cause a plurality of memory cells associated with the identified page to be in a first state; determine an initial read threshold voltage; perform a soft read operation on the plurality of memory cells using the initial read threshold voltage, wherein the soft read operation using the initial read threshold voltage causes a subset of memory cells of the plurality of memory cells to be read as being in a second state that is opposite the first state; determine whether a number of memory cells being read as being in the second state is substantially equivalent to a number of memory cells being read as being in the first state; and based on a determination that the number of memory cells being read as being in the second state is substantially equivalent to the number of memory cells being read as being in the first state, generating an output. In an example, the controller is further configured to receive the output. In an example, the output is a random number represented by the number of memory cells being read as being in the second state and the number of memory cells being read as being in the first state. In an example, identifying the page of the memory die comprises identifying an address of the identified page. In an example, the controller is further configured to cause the address of the identified page to be stored in the data storage device. In an example, the controller is further configured to generate parity bits associated with the output. In an example, the controller is further configured to cause the parity bits to be stored in the data storage device.

Examples of the present disclosure also describe a non-volatile storage device, comprising: a plurality of memory dies; means for identifying a page of the memory die; means for causing a plurality of memory cells associated with the identified page to be in a first state; means for determining an initial read threshold voltage; means for performing a soft read operation on the plurality of memory cells using the initial read threshold voltage, wherein the soft read operation using the initial read threshold voltage causes a subset of memory cells of the plurality of memory cells to be read as being in a second state that is opposite the first state; means for determining whether a number of memory cells being read as being in the second state is substantially equivalent to a number of memory cells being read as being in the first state; and based on a determination that the number of memory cells being read as being in the second state is substantially equivalent to the number of memory cells being read as being in the first state, means for generating an output. In an example, the non-volatile storage device includes means for storing an address associated with the identified page in the non-volatile storage device.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A method for generating a random number using a non-volatile memory based physical unclonable function (PUF), comprising:
identifying a page of a memory die of a non-volatile memory device;
causing a plurality of memory cells associated with the identified page to be in a first state;
determining an initial read threshold voltage;
performing a soft read operation on the plurality of memory cells using the initial read threshold voltage, wherein the soft read operation using the initial read threshold voltage causes a subset of memory cells of the plurality of memory cells to be read as being in a second state that is different than the first state;
determining whether a number of memory cells being read as being in the second state is substantially equivalent to a number of memory cells being read as being in the first state;
based on determining that the number of memory cells being read as being in the second state is substantially equivalent to the number of memory cells being read as being in the first state, generating an output; and
providing the output to a requesting computing device.

2. The method of claim 1, wherein the output is a random number represented by the number of memory cells being read as being in the second state and the number of memory cells being read as being in the first state.

3. The method of claim 1, further comprising determining a second read threshold voltage based on determining that the number of memory cells being read as being in the second state is substantially higher or substantially lower than the number of memory cells being read as being in the first state.

4. The method of claim 3, further comprising:
performing a subsequent soft read operation on the plurality of memory cells using the second read threshold voltage, wherein the subsequent soft read operation using the second read threshold voltage causes a second subset of memory cells of the plurality of memory cells to be read as being in a second state that is different than the first state; and
determining whether a second number of memory cells being read as being in the second state is substantially equivalent to a second number of memory cells being read as being in the first state.

5. The method of claim 4, further comprising:
based on determining that the second number of memory cells being read as being in the second state is substantially equivalent to the second number of memory cells being read as being in the first state, generating the output; and
providing the output to a requesting computing device.

6. The method of claim 1, wherein identifying the page of the memory die comprises identifying an address of the identified page.

7. The method of claim 6, further comprising storing the address of the identified page in the non-volatile memory device.

8. The method of claim 1, further comprising generating parity bits associated with the output.

9. The method of claim 8, further comprising storing the parity bits in the non-volatile memory device.

10. The method of claim 1, wherein the first state is a state in which the plurality of memory cells are in an erased state.

11. The method of claim 1, wherein the first state is a state in which the plurality of memory cells are in a programmed state.

12. A data storage device, comprising:
at least one memory die; and
a controller communicatively coupled to the at least one memory die and configured to:
identify a page of the memory die;
cause a plurality of memory cells associated with the identified page to be in a first state;
determine an initial read threshold voltage;
perform a soft read operation on the plurality of memory cells using the initial read threshold voltage, wherein the soft read operation using the initial read threshold voltage causes a subset of memory cells of the plurality of memory cells to be read as being in a second state that is opposite the first state;
determine whether a number of memory cells being read as being in the second state is substantially equivalent to a number of memory cells being read as being in the first state; and
based on a determination that the number of memory cells being read as being in the second state is substantially equivalent to the number of memory cells being read as being in the first state, generating an output.

13. The data storage device of claim 12, wherein the controller is further configured to receive the output.

14. The data storage device of claim 12, wherein the output is a random number represented by the number of memory cells being read as being in the second state and the number of memory cells being read as being in the first state.

15. The data storage device of claim 12, wherein identifying the page of the memory die comprises identifying an address of the identified page.

16. The data storage device of claim 15, wherein the controller is further configured to cause the address of the identified page to be stored in the data storage device.

17. The data storage device of claim 12, wherein the controller is further configured to generate parity bits associated with the output.

18. The data storage device of claim 17, wherein the controller is further configured to cause the parity bits to be stored in the data storage device.

19. A non-volatile storage device, comprising:
a plurality of memory dies;
means for identifying a page of the memory die;
means for causing a plurality of memory cells associated with the identified page to be in a first state;
means for determining an initial read threshold voltage;
means for performing a soft read operation on the plurality of memory cells using the initial read threshold voltage, wherein the soft read operation using the initial read threshold voltage causes a subset of memory cells of the plurality of memory cells to be read as being in a second state that is opposite the first state;
means for determining whether a number of memory cells being read as being in the second state is substantially equivalent to a number of memory cells being read as being in the first state; and
based on a determination that the number of memory cells being read as being in the second state is substantially equivalent to the number of memory cells being read as being in the first state, means for generating an output.

20. The non-volatile storage device of claim 19, further comprising means for storing an address associated with the identified page in the non-volatile storage device.
